(19) United States
(12) Patent Application Publication
(10) Pub. No.: US 2010/0126417 A1
(43) Pub. Date: May 27, 2010

(54) DEPOSITION SOURCE UNIT, DEPOSITION APPARATUS AND TEMPERATURE CONTROLLER OF DEPOSITION SOURCE UNIT

(75) Inventors: Koyu Hasegawa, Kanagawa (JP); Yuji Ono, Miyagi (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/593,753

(22) PCT Filed: Mar. 25, 2008
(86) PCT No.: PCT/JP2008/055519

§ 371 Date: Sep. 29, 2009

(30) Foreign Application Priority Data
Mar. 30, 2007 (JP) 2007-090538
Mar. 30, 2007 (JP) 2007-095242

(51) Int. Cl. C23C 16/52; C23C 16/00

(52) U.S. Cl. 118/667; 118/726

(57) ABSTRACT

A deposition apparatus includes a deposition source unit, a transport mechanism for transporting a vaporized film forming material and a blowing device for blowing off the transported film forming material. The deposition source unit includes a vapor deposition source assembly, a housing and a water cooling jacket. The vapor deposition source assembly includes a gas supply mechanism, a gas inlet and a first material evaporating chamber formed as one body. A heater of the housing heats a film forming material in the first material evaporating chamber and the carrier gas flowing in a plurality of gas passages. The vaporized film forming material is transported by an argon gas. The water cooling jacket is installed apart from an outer peripheral surface of the housing at a certain distance and cools the deposition source unit.

### TECHNICAL FIELD

The present invention relates to a deposition source unit and a deposition apparatus for forming a desired film on a target object by a vapor deposition method and a method for using the deposition apparatus. Particularly, the present invention pertains to a heating method for a carrier gas.

Further, the present invention relates to a temperature controller of a deposition source unit for forming a desired film on a target object, a temperature control method for the deposition source unit, and a temperature control method for a deposition apparatus. Particularly, the present invention pertains to a temperature control of the deposition source unit by a heating and a cooling, and the deposition apparatus including the deposition source unit.

### BACKGROUND ART

Recently, an organic EL (Electroluminescence) display using an organic EL device, which emits light by using an organic compound, has received considerable attention. Since the organic EL device utilized in the organic EL display has many advantageous characteristics such as self-luminousness, high response time, low power consumption and so forth, a backlight is not necessitated. Thus, application of the organic EL device to, for example, a display unit of a portable device or the like is highly expected.

Such an organic EL device is formed on a glass substrate, and has an organic layer sandwiched between a positive pole (anode) and a negative pole (cathode). If a voltage is applied to the anode and the cathode of the organic EL device, holes are injected into the organic layer from the anode, while electrons are injected into the organic layer from the cathode. Those injected holes and electrons are recombined in the organic layer, so that light is emitted at that time.

In a manufacturing process of such a self-luminous organic EL device, the organic layer is formed by depositing a desired layer by a vapor deposition method. At this time, it is very important to accurately control a film forming rate (D/R: Deposition Rate) of an organic material because luminance of the organic EL device is improved by forming a high-quality film on a substrate after the organic material is gasified completely. For this reason, there has been conventionally proposed a method for controlling the film forming rate by a temperature control of the deposition apparatus (see, for example, Japanese Patent Laid-open Publication No. 2004-220852).

According to this method, a material receptacle is controlled to a desired temperature by heating a heater installed in the material receptacle, whereby a vaporization rate of the organic material is controlled. The vaporized organic material is carried by a carrier gas so as to be adhered to the substrate efficiently. At this time, if there is a temperature gradient between the carrier gas and the vaporized film forming material, the film forming rate of the organic material can not be controlled with high accuracy, so that the organic material may not be completely gasified. As a result, the characteristics of the film formed on the substrate are deteriorated.

For this reason, in the above-described deposition apparatus, a heater is also installed at a pipe for transporting the carrier gas supplied from a carrier gas supply source to the material receptacle so as to prevent the temperature gradient between the carrier gas and the vaporized film forming material, whereby the temperature of the carrier gas flowing in the pipe is controlled by means of heat from the heater.

### DISCLOSURE OF THE INVENTION

### Problems to Be Solved by the Invention

However, when the inside of the deposition apparatus is maintained under a vacuum, the number of gas molecules within the deposition apparatus is very small. Therefore, the probability of collision of a certain gas molecule with a residual gas molecule within the deposition apparatus is very low. Since heat transfer efficiency is poor in such a heat insulation state by vacuum, even when heating is performed to control a certain portion within the deposition apparatus to a desired temperature, it takes a considerable amount of time for the heat to be transferred to that portion. Accordingly, in order to control the temperature of the carrier gas to be substantially same as that of the vaporized film forming material until the carrier gas reaches the material receptacle by flowing in the pipe, the pipe through which the carrier gas passes needs to have a sufficiently long length, which results in scale-up of the deposition apparatus.

The problem of the scale-up of the deposition apparatus is worsened when the flow rate of the carrier gas is high. When the carrier gas flows in a pipe having a uniform diameter, the flow velocity of the carrier gas increases with the rise of the flow rate of the carrier gas, so that heating efficiency by the heater is deteriorated. Accordingly, since the pipe through which the carrier gas passes needs to be further lengthened when the flow rate of the carrier gas is high, larger installation space and more heating equipment are required. However, the scale-up of the deposition apparatus is not desirable for the reason that it causes deterioration of exhaust efficiency and increase of product manufacturing cost.

In view of the foregoing, the present invention provides a deposition source unit and a deposition apparatus capable of improving heating efficiency and exhaust efficiency while reducing an installation space, and a method for using the deposition apparatus.

Meanwhile, if heat is generated from a part of the deposition apparatus, accurate control of the vaporization rate of the film forming material may become difficult because of heat radiation or heat transfer, so that the characteristic of the film formed on the substrate may be degraded. Thus, a structure capable of avoiding heat conduction or radiated heat transfer is necessitated so as to facilitate a temperature control in the vicinity of a material evaporating chamber.

As one example, there is considered a method in which a heating device and a cooling device is arranged as one body and the heating device is directly cooled by flowing a coolant by the cooling device, so that the temperature of the material evaporating chamber can be prevented from increasing to a high temperature due to the heating device, thereby controlling the material evaporating chamber to a desired temperature. However, the heater is typically controlled at a high temperature equal to or higher than about 200° C. Thus, if the cooling device is installed as one body with the heating device such as the heater, the coolant may be vaporized, resulting in damage and malfunction of the cooling device. Accordingly, the heating device and the cooling device can not be arranged integrally.

Further, cooling by natural heat radiation may be considered. However, since the heat transfer efficiency in a vacuum is poor as mentioned above, it takes a considerable amount of time to cool a certain portion of the deposition apparatus to a desired temperature. Thus, this method is unpracticable.

In view of the foregoing, the present invention provides a temperature controller of the deposition source unit capable of carrying out a temperature control efficiently by providing a cooling mechanism away from a heating device at a predetermined distance, and also provides a temperature control method for the deposition source unit, the deposition apparatus and a temperature control method for the deposition apparatus.

### Means for Solving the Problems

In accordance with one aspect of the present invention, there is provided a deposition source unit configured to vaporize a film forming material and transport the vaporized film forming material by a carrier gas, the deposition source unit including: a vapor deposition source assembly; and a housing accommodating the vapor deposition source assembly. The vapor deposition source assembly includes: a first material evaporating chamber configured to accommodate the film forming material therein and vaporize the accommodated film forming material; and a gas supply mechanism having a plurality of gas passages, configured to flow the carrier gas in the gas passages to supply the carrier gas into the first material evaporating chamber. Further, the housing includes a heating mechanism configured to heat the carrier gas flowing in the plurality of gas passages and the film forming material accommodated in the first material evaporating chamber.

Here, the term “vaporization” implies not only the phenomenon that a liquid is converted into a gas but also a phenomenon that a solid is directly converted into a gas without becoming a liquid (i.e., sublimation).

In this configuration, the vapor deposition source assembly having the first material evaporating chamber for accommodating the film forming material therein and the gas supply mechanism for supplying the carrier gas from the plurality of gas passages is accommodated in the housing. Further, the carrier gas flowing in the plurality of gas passages and the film forming material accommodated in the first material evaporating chamber are heated by the heating mechanism installed in the housing.

In this way, the gas supply mechanism is accommodated in the deposition source unit compactly. Accordingly, a flow velocity of the carrier gas flowing through the plurality of gas passages is reduced while it passes through narrow spaces of the gas passages. As a result, the carrier gas flowing in the plurality of gas passages within the deposition source unit can be sufficiently heated by the heating mechanism. In this way, a temperature gradient can not be generated between a temperature of the carrier gas and a vaporization temperature of the film forming material when the carrier gas reaches the first material evaporating chamber. Thus, a film forming rate can be controlled more accurately, and the film forming material can be completely gasified. As a result, a film having a desired characteristic can be formed on a target object.

Further, with this configuration, a long pipe and equipment for heating the long pipe are not necessitated, so that the deposition apparatus can be scaled down. Accordingly, gas exhaust efficiency can be improved and manufacturing cost of the product can be lowered.

The plurality of gas passages of the gas supply mechanism accommodated in the deposition source unit may have various configurations. For example, the gas passages may be provided along a lengthwise direction in parallel to each other.

With this configuration, since the carrier gas flows in the plurality of gas passages arranged in the lengthwise direction in parallel to each other, conductance of the carrier gas flowing in each gas passage can be maintained substantially same. Thus, a flow velocity of the carrier gas flowing in each gas passage can be set to be the substantially same. As a result, the carrier gas flowing in the respective gas passages within the deposition source unit can be heated uniformly, and a temperature gradient can not be generated between the carrier gas introduced in the first material evaporating chamber and the vaporized film forming material. Thus, the film forming material can be completely gasified, and the film forming rate can be controlled highly accurately.

Further, the gas passages may be arranged so as to be uniformly heated by the heating mechanism. In this configuration, the carrier gas flowing in the plurality of gas passages is heated uniformly, and the carrier gas and the vaporized film forming material can be set to be a substantially same temperature. As a result, the film forming rate can be controlled highly accurately, and the film forming material can be gasified completely.

The gas passages may be arranged in multi-levels from a lengthwise central axis of the gas supply mechanism toward an outer periphery thereof. Furthermore, the gas supply mechanism may be formed in a cylindrical shape, and the gas passages may be arranged in a ring shape with respect to a lengthwise central axis of the gas supply mechanism. Alternatively, the plurality of gas passages can be arranged symmetrically or radially with respect to the cylinder-shaped central axis of the gas supply mechanism.

In this way, by installing the plurality of gas passages, the gas supply mechanism can be accommodated in the unit compactly, and heating efficiency for the carrier gas flowing in the plurality of gas passages can be improved. As a result, the carrier gas and the vaporized film forming material can be controlled to the substantially same temperature. Thus, the film forming rate can be controlled accurately and the apparatus can be scaled down.

The vapor deposition source assembly may further include a gas inlet between the first material evaporating chamber and the gas supply mechanism. The gas inlet is configured as a single body with the first material evaporating chamber and the gas supply mechanism evaporating and the gas inlet has an opening for introducing the carrier gas flowing in the gas passages into the first material evaporating chamber.

In this configuration, the carrier gas is introduced into the first material evaporating chamber from the opening of the gas inlet via the plurality of gas passages. For example, by forming the opening of the gas inlet with lattice-patterned pores, a mesh-shaped member and a porous member, the carrier gas can be introduced into the first material evaporating chamber uniformly through the lattice-patterned pores, the openings of the mesh-shaped member or gaps between pores of the porous member while its flow velocity is suppressed. With this configuration, since the carrier gas can be introduced energetically, non-uniform shape of the film forming material accommodated in the first material evaporating chamber can be prevented (see FIGS. 7A and 7B).

The non-uniform shape of the film forming material is not desirable because it causes a change in a vaporizing rate of the film forming material due to a change in a contact state between a wall surface of the material receptacle and the film forming material, thus resulting in a fluctuation of a film forming rate and incomplete gasification of the film forming material. In this way, if a film formation is performed by the incompletely gasified film forming material, a quality of an obtained film may be degraded, resulting in a deterioration of brightness of an organic EL device.

With the above-described configuration, however, since the non-uniform shape of the film forming material can be prevented, the film forming rate can be controlled with high accuracy. Therefore, the film forming material can be completely gasified, and a high-quality film can be formed on the target object.

The opening of the gas inlet may be installed apart from a material input port provided in the first material evaporating chamber at a preset distance. Further, the opening of the gas inlet may be formed by any one of lattice-patterned pores, a mesh-shaped member and a porous member.

In this configuration, the carrier gas is transported into the first material evaporating chamber at a position distanced apart from the film forming material accommodated in the first material evaporating chamber. Further, when the carrier gas passes through the lattice-patterned pores, the openings of the mesh-shaped member or gaps between pores of the porous member, it is transported into the first material evaporating chamber after its flow velocity is reduced. Accordingly, non-uniform shape or backflow of the film forming material due to an influence of a flow of the transported carrier gas can be avoided. As a result, the film forming rate can be controlled highly accurately, and a deterioration of material efficiency due to the backflow of the material and a reduction of an apparatus maintenance cycle can be avoided. Thus, the manufacturing cost can be reduced, while throughput is improved during the manufacture.

The gas inlet may include a buffer space that temporarily stores the carrier gas between outlets of the gas passages and the opening of the gas inlet. In this configuration, while the carrier gas is staying in the buffer region temporarily via the gas passages, the flow velocity of the carrier gas can be reduced and uniform. Thus, non-uniform shape or backflow of the film forming material can be prevented, so that the high-quality film can be formed on the target object.

The heating mechanism may be a heater installed at an outer periphery of the housing. In this configuration, the vapor deposition source assembly in the housing can be effectively heated by the heater installed at the outer periphery of the housing. Thus, heating efficiency can be improved, and the apparatus can be scaled down. As a result, the high-quality film can be formed on the target object by controlling the film forming rate accurately. Further, by improving the gas exhaust efficiency, improvement of throughput and reduction of manufacturing cost can be accomplished.

The housing may accommodate the vapor deposition source assembly in a detachable manner. In this configuration, since the material receptacle is detachable without being fixed to the deposition apparatus, replenishment of the material can be performed easily.

A cover having lattice-patterned pores, mesh-shaped openings or hole-shaped openings may be detachably installed at the first material evaporating chamber. In this configuration, the vaporized film forming material can fly to the outside of a receptacle from the mesh-shaped openings or holes, so that a backflow of the film forming material in the receptacle can be prevented.

The housing may include a transfer path for transferring the film forming material vaporized from the first material evaporating chamber, and the deposition source unit may connect the transfer path to an external transport path so as to transport the film forming material from the transfer path to the transport path and may blow off the transported film forming material from a blowing device.

In this configuration, the film forming material vaporized in the first material evaporating chamber is efficiently transported through the transfer path by the carrier gas and then is blown off from the blowing device after reaching the blowing device via the transport path. Thus, the vaporized film forming material can be adhered to the target object while controlling the film forming rate with high accuracy. As a result, the high-quality film can be formed on the target object.

The deposition source unit may further include a second material evaporating chamber installed at a position within the transfer path, configured to further vaporize the film forming material. The second material evaporating chamber is installed at a position closer to the transport path than the first material evaporating chamber. Since the transport path is typically controlled to about 450° C., a temperature of the second material evaporating chamber is typically higher than a temperature of the first material evaporating chamber U. Accordingly, the film forming material passing through the transfer path is further vaporized in the second material evaporating chamber. Accordingly, the film forming material carried by the carrier gas without having been completely gasified can be vaporized completely again. As a result, a higher-quality film can be uniformly formed on the substrate, and the material efficiency can be improved.

The second material evaporating chamber may be formed by any one of lattice-patterned pores, a mesh-shaped member and a porous member. In this configuration, the incompletely gasified film forming material can be sufficiently vaporized when it passages through the lattice-patterned pores, the openings of the mesh-shaped member or gaps between pores of the porous member.

In accordance with another aspect of the present invention, there is provided a deposition apparatus including: a deposition source unit configured to vaporize a film forming material and carry the vaporized film forming material by a carrier gas; a transport path connected to the deposition source unit, for transporting the film forming material vaporized in the deposition source unit; and a blowing device connected to the transport path, for blowing off the film forming material transported through the transport path. The deposition source unit includes a vapor deposition source assembly and a housing accommodating the vapor deposition source assembly. Further, the vapor deposition source assembly includes: a first material evaporating chamber configured to accommodate the film forming material therein and vaporize the accommodated film forming material; and a gas supply mechanism having a plurality of gas passages, configured to flow the carrier gas in the gas passages to supply the carrier gas into the first material evaporating chamber. Further, the housing includes a heating mechanism configured to heat the carrier gas flowing in the plurality of gas passages and the film forming material accommodated in the first material evaporating chamber.

In accordance with still another aspect of the present invention, there is provided a method for using a deposition apparatus including a deposition source unit configured to vaporize a film forming material and carry the vaporized film forming material by a carrier gas; a transport path connected to the deposition source unit, for transporting the vaporized film forming material; and a blowing device connected to the transport path, for blowing off the film forming material transported through the transport path. The vapor deposition source unit includes a vapor deposition source assembly and a housing accommodating the vapor deposition source assembly. The method includes: vaporizing the film forming material accommodated in a first material evaporating chamber by heating the film forming material in the first material evaporating chamber provided in vapor deposition source assembly by a heating mechanism installed at the housing; flowing the carrier gas through a plurality of gas passages formed in a gas supply mechanism installed in the vapor deposition source assembly, while heating the carrier gas by the heating mechanism; and introducing the heated carrier gas into the first material evaporating chamber from lattice-patterned pores, mesh-shaped openings or openings between pores, which are provided in the vapor deposition source assembly.

In this configuration, the carrier gas can be efficiently heated within the deposition source unit by the gas supply mechanism compactly accommodated in the deposition source unit. Accordingly, a temperature gradient can not be generated between a temperature of the carrier gas reaching the first material evaporating chamber and a vaporization temperature of the film forming material, so that the film forming rate can be maintained uniform. As a result, the film forming material can be completely gasified, thus enabling the formation of the high-quality film. Furthermore, according to this configuration, since the deposition source unit can be scaled down, gas exhaust efficiency can be improved, so that manufacturing cost and unnecessary equipment investment can be reduced.

In accordance with still another aspect of the present invention, there is provided a temperature controller for controlling a temperature of a deposition source unit that is installed in a vacuum and vaporizes a film forming material and carries the vaporized film forming material by a carrier gas. The deposition source unit includes a plurality of gas passages for flowing therein the carrier gas which carries the vaporized film forming material. The temperature controller includes: a heating mechanism installed in the deposition source unit, configured to heat the carrier gas flowing in the plurality of gas passages; and a cooling mechanism installed apart from the heating mechanism at a preset distance, configured to cool the deposition source unit.

Further, the cooling mechanism may have a cooling jacket installed apart from the deposition source unit at a preset distance so as to cover the deposition source unit. Furthermore, the cooling mechanism may have a mechanism for flowing a coolant in partition walls configured to divide the plurality of blowing devices in the vicinity of the deposition source unit. Further, the heating mechanism may include a heater installed at an outer periphery of the housing.

In this configuration, the deposition source unit including the plurality of gas passages therein can be controlled up to a desired temperature with high responsiveness by the heating mechanism installed in the temperature controller and the cooling mechanism apart from the heating mechanism at a certain distance. That is, the temperature controller cools the deposition source unit to a temperature slightly lower than a target temperature, and then heats the carrier gas supplied in the plurality of gas passages to a desired temperature by the heating mechanism.

As described above, the cooling mechanism is installed apart from the heating mechanism at a certain distance and a specific portion serving as a temperature control target is previously cooled down to the temperature slightly lower than the target temperature, whereby the heating mechanism can quickly control the specific portion up to the target temperature even in a vacuum where the heat transfer efficiency is poor. Further, by absorbing the heat generated from the heating mechanism by the cooling mechanism, a heat transfer to a component except the specific portion as a target can be prevented. Accordingly, the temperature of the carrier gas can be quickly and accurately controlled to be the same as that of the film forming material vaporized from the material receptacle even in the vacuum. As a result, a high-quality film can be formed on a target object.

The deposition source unit may be cooled by allowing a coolant to flow in the cooling mechanism. Desirably, water may be used as the coolant in consideration of manufacturing cost.

The cooling mechanism may be installed apart from the heating mechanism at a preset distance. In this configuration, since the distance from the heating mechanism to the cooling mechanism is equal, the heating mechanism can be cooled uniformly by the cooling mechanism. Accordingly, a transfer of heat generated from the heating mechanism to the vicinity of the material receptacle can be avoided effectively. Thus, the temperature in the vicinity of the material receptacle can be controlled more accurately.

At this time, the deposition source unit may include: a first material evaporating chamber for accommodating a film forming material therein and vaporizing the accommodated film forming material; a vapor deposition source assembly having the plurality of gas passages; and a housing accommodating the vapor deposition source assembly. The heating mechanism may be installed in the vicinity of an outer periphery of the housing, and the cooling mechanism may be installed apart from an outer peripheral surface of the housing at a preset distance.

In this configuration, since the deposition source is compactly designed as a unit integrating the vapor deposition source assembly and the housing, the heating efficiency of the carrier gas can be improved, and the overall size of the apparatus can be reduced. As a result, improvement of throughput and reduction of manufacturing cost can be accomplished by improving gas exhaust efficiency.

A surface of the cooling mechanism facing the housing may have a predetermined surface roughness. Further, a surface of the housing facing the cooling mechanism may have a predetermined surface roughness.

In this configuration, by roughening the facing surfaces of the cooling mechanism or the housing, their surface areas can be enlarged. Accordingly, the housing can radiate the heat generated by the heating mechanism to the outside effectively, and the cooling mechanism can effectively absorb the heat generated by the hosing (heating mechanism) to the inside thereof.

A surface of the cooling mechanism facing the housing may be processed so as to absorb heat readily. Further, a surface of the housing facing the cooling mechanism may be processed so as to radiate heat readily.

In this configuration, the housing radiates external heat whereas the cooling mechanism absorbs it. As a result, by allowing the housing to have a high heat radiation rate and the cooling mechanism to have a high heat absorption rate, the housing can be more efficiently cooled by the cooling mechanism even under the vacuum where a heat transfer efficiency is poor, and an excessive temperature rise of the inside of the deposition source unit can be prevented. Furthermore, the cooling mechanism's surface facing the housing and the housing's surface facing the cooling mechanism may be undergone through surface processing such as sandblast to improve the heat radiation rate and the heat absorption rate.

The vapor deposition source assembly may be detachably accommodated in the housing. In this configuration, since the material receptacle is not fixed to the deposition apparatus and is separated therefrom, the material can be replenished easily. Further, in conventional maintenance for the material replenishment or the like, the operation of the apparatus has to be stopped for almost a day until the deposition source is naturally cooled down. In accordance with the above-described configuration, however, maintenance time can be shortened because the deposition source unit is compulsively cooled by the cooling mechanism.

The housing may include a transfer path for transferring the film forming material vaporized in the first material evaporating chamber, and the transfer path may be connected with an external blowing device installed outside via an external transport path so as to blow off the film forming material, which is transferred through the transfer path, from the blowing device.

When the vaporized film forming molecules flow in the transport path along with the carrier gas, the temperature of the transport path needs to be set to be higher than a temperature in the vicinity of the material receptacle in order to adhere a greater amount of vaporized film forming molecules to the target object, while the vaporized film forming molecules are hardly adhered to the transport path. It is because an increase of the temperature of the transport path accompanies a decrease of adhesion coefficient, and also makes the vaporized film forming molecules more difficult to be adhered to the transport path. Thus, the temperature of the transport path is controlled to, e.g., about 450° C.

In this way, if the temperature of the transport path is set to be high, heat may be generated from the vicinity of the transport path, and the heat is transferred to the vicinity of the material receptacle by heat conductance or radiation, thus making it difficult to control the temperature in the vicinity of the material receptacle. Thus, there is a demand for a method that suppresses heat transfer by heat conductance or radiation in order to facilitate the temperature control in the vicinity of the material receptacle.

In the above configuration, radiated heat or conducted heat is absorbed by the cooling mechanism installed apart from the transport path at a certain distance. Thus, the vaporized film forming material is not affected by the heat generated from the transport path, so that it can be efficiently transported to the blowing device without being adhered to the transport path. As a result, a high-quality film can be formed on the target object by the vaporized film forming molecules blown off from the blowing device after reaching the blowing device via the transport path.

The deposition source unit may have a bottle-shaped neck portion which is narrowed at a position where the transport path of the transport mechanism 200 and the transfer path 115 is connected with each other.

The bottle-shaped front portion (connection portion between the transfer path and the transport path, that is, neck portion) of the deposition source unit has a small cross section, so that it has a higher heat resistance than that of the body portion (head portion) having a large cross section. With this configuration, the heat resistance of the neck portion of the deposition source unit can be set to be higher than that of the head portion of the deposition source unit. That is, heat transfer efficiency from the transport mechanism to the head portion of the deposition source unit via the neck portion thereof can be lowered. Accordingly, an excessive temperature rise of the first material evaporating chamber U in the head portion of the deposition source unit can be suppressed.

A connection portion between the transfer path and the transport path may be sealed by a metal seal. In this configuration, even in case that the transport path is controlled to a high temperature, the connection portion between the transfer path and the transport path can be securely sealed by the metal seal having high heat resistance.

Moreover, the connection portion of the transfer path and the transport path may be in contact with only the metal seal without contacting with any other material. In this configuration, since a non-contact portion is configured as a vacuum space, thermal conductivity from the transport path to the deposition source unit can be reduced by heat insulation by vacuum. As a result, a temperature gradient is generated between the transport path and the deposition source unit, so that an excessive temperature rise of the inside of the deposition source unit can be prevented.

In accordance with another aspect of the present invention, there is provided a method for controlling a temperature of a deposition source unit installed in a vacuum and configured to vaporize a film forming material and carry the vaporized film forming material by a carrier gas. The method includes: flowing the carrier gas for transporting the vaporized film forming material through a plurality of gas passages provided in the deposition source unit; heating the carrier gas which is flowing through the plurality of gas passages by a heating mechanism installed in the deposition source unit; and cooling the deposition source unit by a cooling mechanism installed apart from the heating mechanism at a preset distance.

In accordance with still another aspect of the present invention, there is provided a deposition apparatus installed in a vacuum and including a deposition source unit configured to vaporize a film forming material and carry the vaporized film forming material by a carrier gas; a transport path connected to the deposition source unit, for transporting the film forming material vaporized in the deposition source unit; and a blowing device connected to the transport path, for blowing off the film forming material transported through the transport path. The deposition apparatus includes: a plurality of gas passages configured to flow therein a carrier gas for carrying the film forming material vaporized in the deposition source unit; a heating mechanism configured to heat the carrier gas flowing in the plurality of gas passages; and a cooling mechanism configured to cool the deposition source unit apart from the heating mechanism at a preset distance.

At this time, the cooling mechanism may be provided in at least one of a plurality of deposition source units connected to the transport path.

In this configuration, the cooling mechanism can prevent an excessive temperature rise of the inside of the deposition source unit due to heat radiated from the adjacent deposition source unit as well as from heat conductance or radiated heat from the transport path. At this time, in case that the deposition source units connected to the transport path are more than two, it may be desirable to install the cooling mechanism at every deposition source unit. In case that the cooling mechanism cannot be installed at every unit, however, it may be desirable to first provide the cooling mechanism at a deposition source unit in a central position, which is most highly likely to be affected by the heat radiated from each deposition source unit, or at a deposition source unit having a lowest control temperature.

In accordance with still another aspect of the present invention, there is provided a method for controlling a temperature of a deposition apparatus installed in a vacuum and including a deposition source unit configured to vaporize a film forming material and carry the vaporized film forming material by a carrier gas; a transport path connected to the deposition source unit, for transporting the film forming material vaporized in the deposition source unit; and a blowing device connected to the transport path, for blowing off the film forming material transported through the transport path. The method includes: accommodating the film forming material in a first material evaporating chamber and vaporizing the accommodated film forming material in the first material evaporating chamber; flowing the carrier gas in a gas supply mechanism having a plurality of gas passages; and cooling the deposition source unit by a cooling mechanism installed apart from an outer peripheral surface of a housing for accommodating the first material evaporating chamber and the gas supply mechanism at a preset distance; and heating the first material evaporating chamber and the gas supply mechanism by a heating mechanism installed in the housing.

In this configuration, the carrier gas can be heated to a desired temperature after the deposition source unit is cooled by the cooling mechanism. Accordingly, the temperature of each component of the deposition apparatus can be controlled quickly and accurately even in a vacuum where a heat transfer efficiency is poor.

### EFFECT OF THE INVENTION

In accordance with the present invention as stated above, by heating the carrier gas to the substantially same temperature as that of the vaporized film forming material after cooling the deposition source unit to a desired temperature by the cooling mechanism installed apart from the heating mechanism at a certain distance, the film forming rate can be controlled accurately even in a vacuum, so that the high-quality film can be formed on the target object.

### BRIEF DESCRIPTION OF THE DRAWINGS

The disclosure may be best understood by reference to the following description taken in conjunction with the following figures:

FIG. 1 shows a schematic configuration view of a cluster type substrate processing apparatus in accordance with an embodiment and each modification example of the present invention;

FIG. 2 shows a schematic view of a deposition apparatus in accordance with the embodiment and each modification example of the present invention;

FIG. 3 shows a view for illustrating each layer of an organic EL device formed by the deposition apparatus in accordance with the embodiment and each modification example of the present invention;

FIG. 4A is a longitudinal cross-sectional view of the deposition apparatus in accordance with the embodiment of the present invention;

FIG. 4B is a cross sectional view taken along a surface B-B of FIG. 4A;

FIG. 5A is a cross sectional view of a deposition source unit including a water cooling jacket in accordance with the embodiment of the present invention;

FIG. 5B is a table for showing a simulation result of cooling effect obtained by using the water cooling jacket in accordance with the embodiment of the present invention;

FIG. 6A is a cross sectional view of gas passages of a gas supply mechanism in accordance with the embodiment and each modification example of the present invention;

FIG. 6B is a cross sectional view of a gas introduction plate in accordance with the embodiment and each modification example of the present invention;

FIG. 7A is a view for explaining an effect of a gas introduction plate in accordance with the embodiment and each modification example of the present invention;

FIG. 7B is a view for explaining an effect of a gas introduction plate in accordance with the embodiment and each modification example of the present invention;

FIG. 8 is a graph for showing a relationship between a length of the gas passages of the gas supply mechanism and a gas temperature in accordance with the embodiment of the present invention;

FIG. 9 is a cross sectional view of the deposition source unit in accordance with a first modification example and a second modification example;

FIG. 10 is a view for explaining a quantity of heat received by the deposition source unit in accordance with the embodiment of the present invention;

FIG. 11 is a graph for showing a temperature rise in response to a quantity of heat received by the deposition source unit in accordance with the embodiment of the present invention; and

FIG. 12 is a view for showing an effect obtained when the water cooling jacket is installed at the deposition source unit in accordance with the embodiment of the present invention.

### EXPLANATION OF CODES

10: Substrate processing apparatus
20: Deposition apparatus
100: Deposition source unit
105: Gas supply mechanism
105p: Gas passages
110: Material receptacle
115: Transfer path
120: Heater
125: Gas inlet
125a: Plate-shaped member
125b: Gas introduction plate
130: Gas supply port
135, 140: Flanges
160: second material evaporating chamber
165: Cover
170: Metal seal
200: Transport mechanism
205: Transport path
300: Valves
400: Blowing device
500: Partition walls
600: Vapor deposition device
Hu: Housing
As: Vapor deposition source assembly
U: First material evaporating chamber
B: Buffer space

### BEST MODE FOR CARRYING OUT THE INVENTION

Hereinafter, an embodiment of the present invention will be described in detail with reference to the accompanying drawings. Through the whole document, same reference numerals denote like components that have same structure and same function, and redundant description will be omitted. In the specification, 1 mTorr is 10⁻³×101325/760 Pa, and 1 sccm is 10⁻⁶/60 m³/sec.

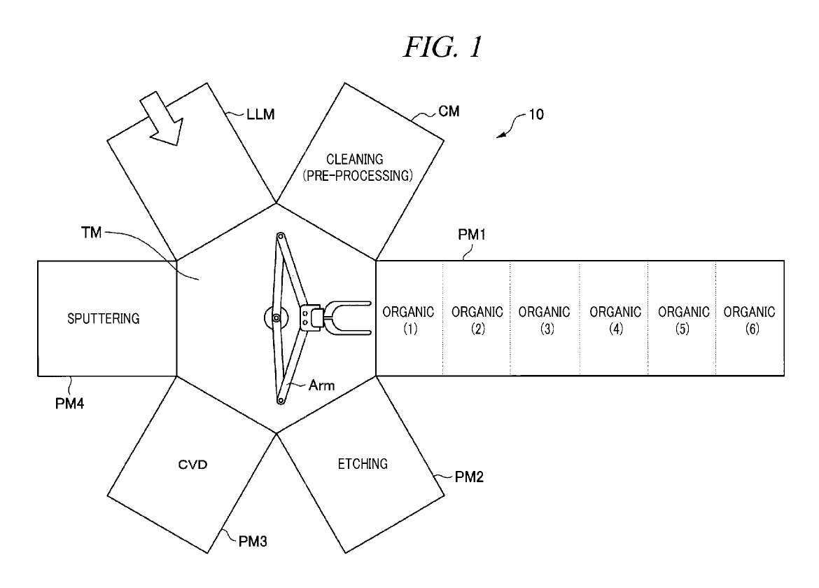

First, a schematic configuration of a substrate processing apparatus 10 in accordance with the embodiment of the present invention will be explained with reference to FIG. 1. In the present embodiment, a manufacturing process of an organic light emitting diode, which is performed by the substrate processing apparatus 10, will be described.

(Manufacturing Process of an Organic Light Emitting Diode)

The substrate processing apparatus 10 in accordance with the present embodiment is a cluster manufacturing apparatus including a plurality of processing chambers, and it has a load lock module LLM, a transfer module TM, a pre-process module CM and four process modules PM1 to PM4.

The load lock module LLM is a vacuum transfer chamber whose inside is maintained in a depressurized state to transfer a glass substrate (hereinafter, simply referred to as a “substrate”) G from the atmosphere into the transfer module TM in a depressurized state. Further, ITO (Indium Tin Oxide) serving as an anode is previously formed on the substrate G to be transferred from the atmosphere into the load lock module LLM.

A multi-joint transfer arm Arm capable of making extending/retracting and rotating motions is installed in the transfer module TM. The substrate G is first transferred from the load lock module LLM into the pre-process module CM by using the transfer arm Arm and then is transferred into the process module PM1 and then into the other process modules PM2 to PM4. The pre-process module CM removes contaminants (mostly organic substances) adhered on the surface of the ITO formed on the substrate G as the anode.

Processes for manufacturing an organic light emitting diode are respectively performed in the four process modules PM1 to PM4. First, 6 organic layers are consecutively formed on the ITO of the substrate in the process module PM1 by vapor deposition. Then, the substrate G is transferred into the process module PM4, and a metal electrode (cathode layer) is formed on the organic layers of the substrate G by sputtering. Thereafter, the substrate G is transferred into the process module PM2, and an unnecessary portion is removed by etching. Then, the substrate G is transferred into the process module PM3, and a sealing film for sealing the organic layers is formed thereon by CVD.

(Consecutive Film Formation of Organic Layers)

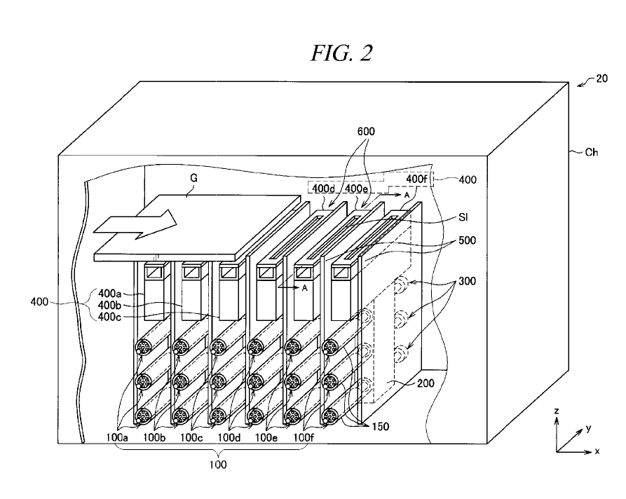

Now, a process of consecutively forming 6 organic layers in the process module PM1 will be explained with reference to FIG. 2, which provides a schematic perspective view of a deposition apparatus. The deposition apparatus 20 includes a rectangular processing chamber Ch. The deposition apparatus 20 includes, in the processing chamber Ch, 6 sets of three deposition source units 100a to 100f, 6 sets of transport mechanism 200, 6 sets of three valves 300, 6 sets of blowing device 400a to 400f, and seven partition walls 500. The inside of the processing chamber Ch is maintained at a predetermined vacuum level by a non-illustrated gas exhaust unit. Further, each set of three deposition source units 100, one transport mechanism 200, three valves 300 and one blowing device 400 will be referred to as a vapor deposition device 600 and the respective set is divided by partition wall 500.

The 6 sets of three deposition source units 100 have water cooling jackets 150 for covering the respective deposition source units 100. The 6 sets of three deposition source units 100 and the water cooling jackets 150 have same cylindrical external shape and internal configuration, and different kinds of film forming materials are accommodated in the deposition source units 100. The 6 sets of one transport mechanism 200 have same rectangular external shapes and are arranged in parallel to each other at a same distance such that one lengthwise (Z-directional) end of each is fixed to a bottom wall of the deposition apparatus 20 while the other end is configured to support the blowing device 400. Each transport mechanism 200 is connected to the three deposition source units 100 such that the three deposition source units 100 are arranged on one sidewall thereof at a same distance in parallel, and each transport mechanism 200 is also connected to the three valves 300 on an opposite sidewall. The three valves 300 are arranged at equi-spaced positions facing the deposition source units 100. In this way, the three deposition source units 100 and their water cooling jackets 150 are arranged at the same distance in parallel to each other. Further, the three valves 300 are connected to the transport mechanism 200 at positions facing the deposition source units.

The six blowing devices 400 respectively held on the six transport mechanisms 200 have a same structure of a rectangular shape whose inside is partially hollow, and are arranged in parallel to each other at a same distance. With this configuration, film forming molecules vaporized from each deposition source unit 100 are blown off from an opening S1 provided in the center of a top portion of each blowing device 400 after passing through each transport mechanism 200.

The seven partition walls 500 are arranged in parallel to each other at a same interval so as to separate adjacent vapor deposition devices 600 from each other, and serve to prevent a mixture of film forming molecules blown off from the top opening S1 of each blowing device 400 with film forming molecules blown off from an adjacent blowing device 400. The deposition source unit 100 is allowed to be cooled by way of flowing water in the partition wall 500 (not shown). A non-illustrated sliding mechanism is configured to move the substrate G in a horizontal direction slightly above each blowing device 400 while attracting the substrate G electrostatically.

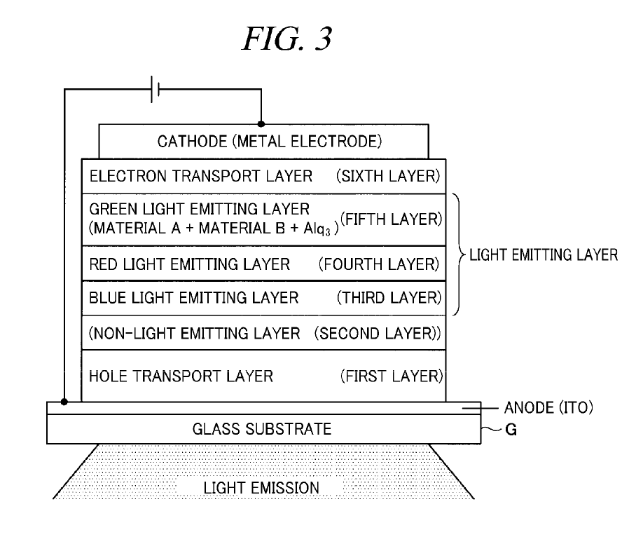

FIG. 3 provides a result of performing a 6-layer consecutive film forming process by using the deposition apparatus 20 configured as described above. First, while the substrate W is being moved above a first blowing device 400a at a certain speed, a film forming material blown off from the first blowing device 400a is adhered to the substrate G, so that a hole transport layer as a first layer is formed on the substrate W. Subsequently, while the substrate G is being moved above a second blowing device 400b, a film forming material blown off from the second blowing device 400b is adhered to the substrate G, so that a non-light emitting layer (electron blocking layer) as a second layer is formed on the substrate G. In like manner, while the substrate G is being moved from a third blowing device 400c to a sixth blowing device 400f in sequence, a blue light emitting layer as a third layer, a red light emitting layer as a fourth layer, a green light emitting layer as a fifth layer and an electron transport layer as a sixth layer are formed on the substrate G by film forming materials blown off from the respective blowing device. In this way, by forming the six layers of organic films consecutively within the same processing chamber of the deposition apparatus 20, throughput and productivity can be improved. Further, since a plurality of chambers (processing chambers) need not be installed for different types of organic films unlike conventional cases, a scale-up of the equipment is not caused, so that equipment cost can be reduced.

(Transport Path)

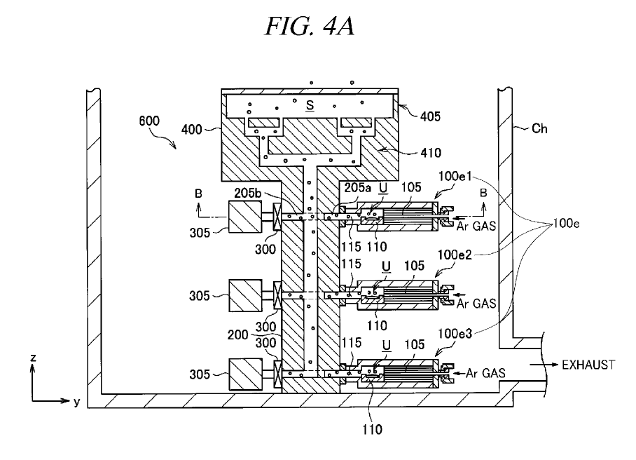

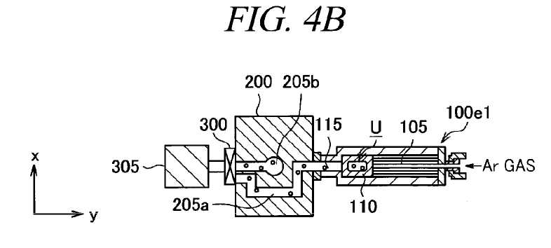

Now, a transport path of a film forming material vaporized from each deposition source unit 100 until it is blown off from the opening S1 of each blowing device 400 will be explained. As stated above, since the six vapor deposition devices 600 have the same structure, a vapor deposition device 600 for forming the fifth layer will be elaborated with reference to FIG. 4A and FIG. 4B, which provide longitudinal cross sectional views of the deposition apparatus 20 taken along a surface A-A of FIG. 2, and thus description of other vapor deposition devices 600 will be omitted.

As shown in FIG. 4A, deposition source units 100e1 to 100e3 have the same internal configuration. An end of the deposition source unit 100e is connected with a non-illustrated argon gas supply source so that an argon gas outputted from the argon gas supply source is supplied into the deposition source unit 100e. The deposition source unit 100e, previously cooled by the water cooling jacket 150, allows the argon gas to flow in a gas supply mechanism 105 while heating the argon gas and then transports the argon gas heated to a desired temperature into a first material evaporating chamber U. In the first material evaporating chamber U, an organic film forming material is accommodated in a material receptacle 110, and the organic film forming material is vaporized by heating the material receptacle 110.

The vaporized film forming material flows in a transfer path 115 toward the transport mechanism 200 by a diffusion phenomenon using the argon gas introduced in the first material evaporating chamber U as a carrier gas. As illustrated in FIG. 4B which provides a transversal cross sectional view of the vapor deposition device 600 taken along a surface B-B of FIG. 4A, organic molecules and the carrier gas flow into a main passage 205b from a bypass passage 205a of the transport path formed within the transport mechanism 200 via the valve 300 after passing through the transfer path 115, and they are sent toward the blowing device 400, as shown in FIG. 4A.

The valve 300 is provided with a lever 305 for opening and closing the valve 300. If the valve 300 is closed by the lever 305, the film forming material and the carrier gas are blocked by the valve 300 and are no more transported. If the valve 300 is opened by the lever 305, the film forming material and the carrier gas are transported into the main passage 205b of the transport path through the valve 300. In this way, among the organic molecules vaporized from the deposition source units 100e1 to 100e3, only the organic molecules necessary for film formation are allowed to pass through the main passage 205b of the transport path and are transported up to the blowing device 400 while mixed with each other.

The blowing device 400 has a blowing unit 405 in its upper portion and has a branch unit 410 in its lower portion. The blowing unit 405 has a hollow internal space S and the opening S1 opened in the center of its top surface as illustrated in FIG. 2. The organic molecules transported to the blowing device 400 by the carrier gas pass through one of four branch passages 410 arranged such that the distances from a branch source to respective branch destinations are all the same so as to make the conductance of the carrier gas and the organic molecules passing through the branch passages 410 uniform and then the organic molecules are blown off toward the substrate G from the opening S1 communicating with the space S within the blowing unit 405.

(Internal Configuration of Deposition Source Unit)

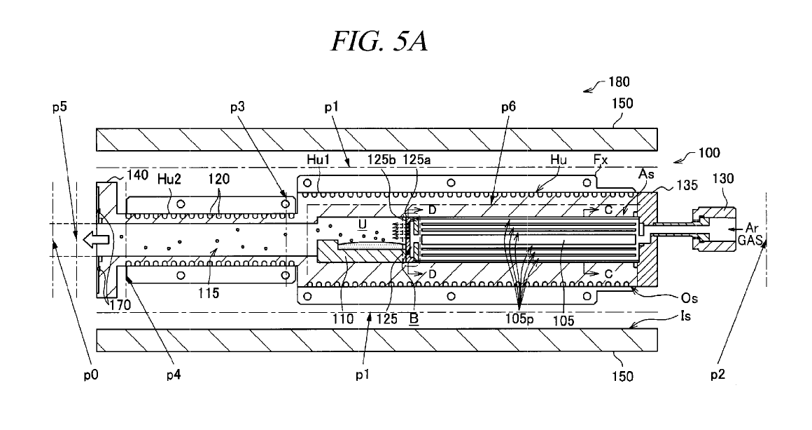

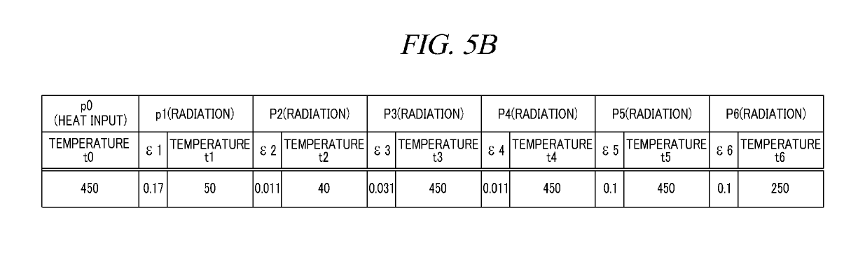

Now, an internal configuration of the deposition source unit 100 of the deposition apparatus 20 in accordance with the above-stated present embodiment will be explained with reference to a cross sectional view of the deposition source unit 100 shown in FIG. 5A.

The deposition source unit 100 includes a vapor deposition source assembly As; a housing Hu configured to accommodate the vapor deposition source assembly As; and a cover Fx for covering the housing Hu. The vapor deposition source assembly As, the housing Hu and the cover Fx are made of, e.g., stainless steel. The housing Hu has a bottle-shaped structure having a difference in a diameter. That is, the housing Hu includes a large-diameter annular portion (head portion Hu1 of the deposition source unit) and a small-diameter annular portion (neck portion Hu2 of the deposition source unit). A hollow space in the large-diameter annular portion (head portion Hu1 of the deposition source unit) communicates with a hollow space in the small-diameter annular portion (neck portion Hu2 of the deposition source unit). The vapor deposition source assembly As is detachably installed in the housing Hu, so that a film forming material vaporized within the housing Hu can be transported by a carrier gas.

A heater 120 is buried in the entire outer peripheral surface of the housing Hu in a spiral pattern. The heater 120 is an example of a heating mechanism that heats the carrier gas and the film forming material. The cover Fx covers the housing Hu so as to allow the heater 120 to be pressed from the outside.

The vapor deposition source assembly As includes the first material evaporating chamber U, the gas supply mechanism 105, a gas inlet 125, a gas supply port 130 for supplying the carrier gas, and a flange 135. The material receptacle 110 is installed in a bottom portion of the first material evaporating chamber U. The organic film forming material used for forming each layer of FIG. 3 is accommodated in the material receptacle 110. The first material evaporating chamber U and the transfer path 115 communicate with each other.

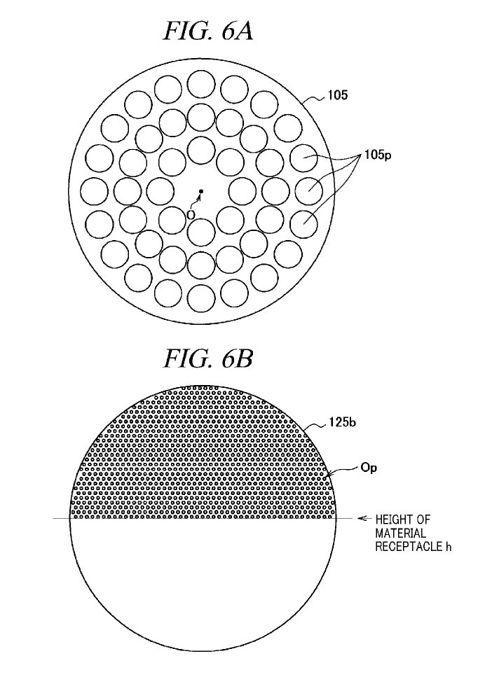

The gas supply mechanism 105 has a cylindrical shape, and a plurality of gas passages 105p are arranged therein in multi-levels. The gas passages 105p in the present embodiment are provided in a lengthwise direction in parallel to each other and have same diameter. As shown in FIG. 6A which provides a cross sectional view of the gas supply mechanism 105 taken along a surface C-C of FIG. 5A, the gas passages 105p are arranged in multi-levels to have the ring shape with respect to a lengthwise central axis O of the gas supply mechanism 105 formed in the cylindrical shape.

In this way, by providing the plurality of gas passages 105p within the deposition source units 100 in a regular manner, a flow velocity of the carrier gas can be reduced while it is flowing through the narrow gas passages 105p. Accordingly, the carrier gas passing through the gas passages 105p can be sufficiently heated by the heater 120. As a result, the carrier gas can be sufficiently heated up to a temperature substantially equal to a vaporization temperature of the film forming material until it reaches the first material evaporating chamber. With this configuration, a highly accurate control of film forming rate is enabled, so that the film forming material can be completely gasified and a high-quality film can be formed uniformly and stably.

Further, the gas passages 105p are arranged so that they may be uniformly heated by the heater 120. Thus, the carrier gas flowing through the respective gas passages 105p can be heated uniformly, so that the carrier gas and the vaporized film forming material transported into the first material evaporating chamber can have a substantially same temperature. As a result, the film forming rate can be controlled with high accuracy.

The gas inlet 125 is provided between the first material evaporating chamber U and the gas supply mechanism 105 and is configured as one body with the first material evaporating chamber U and the gas supply mechanism 105, and serves to introduce the carrier gas flown through the gas passages 105p into the first material evaporating chamber U. The gas inlet 125 includes a plate-shaped member 125a configured to concentrate the argon gas passed through the plurality of gas passages 105p of the gas supply mechanism 105 and having a central opening through which the concentrated argon gas is introduced into a buffer space B; and a gas introduction plate 125 configured to introduce the argon gas in the buffer space B into the first material evaporating chamber U through a number of fine holes.

As illustrated in FIG. 6B which provides a cross sectional view of the gas introduction plate 125b taken along a surface D-D of FIG. 5A, the gas introduction plate 125b is provided with a set of fine holes Op. The fine holes Op have a diameter φ of about 0.5 mm and are arranged in a lattice pattern. The set of fine holes Op is provided at a position higher than a height h of a material input port of the material receptacle 110. Alternatively, instead of the lattice-patterned holes, a mesh-shaped member or a porous member having a predetermined porosity may be employed in the gas introduction plate 125b.

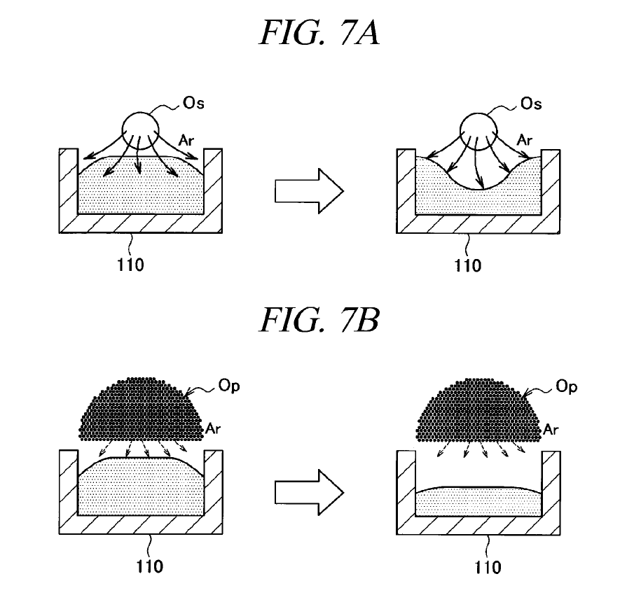

As illustrated in FIG. 7A, if a relatively large opening Os is formed in the gas introduction plate 125b, the argon gas may be introduced toward the film forming material at a considerably high flow velocity, so that the shape of the film forming material becomes non-uniform. The non-uniform shape of the film forming material is not desirable because it causes a change in a vaporizing rate of the film forming material due to a change of a contact state between a wall surface of the material receptacle 110 and the film forming material, thus resulting in a fluctuation of a film forming rate. Further, the non-uniform shape of the film forming material may impede the gasification of the film forming material. If a film formation is performed by the incompletely gasified film forming material, the quality of an obtained film may be degraded, resulting in a deterioration of brightness of an organic EL device.

However, in the deposition source unit 100 in accordance with the present embodiment, even if the conductance of the argon gas flowing in the plurality of gas passages 105p provided in the gas supply mechanism 105 are non-uniform, a difference in the conductance may be absorbed while the argon gas is being transported from the opening provided in the center of the plate-shaped member 125a into the buffer space B, so that the flow velocity of the argon gas can be reduced and uniform.

While the gas flow is controlled in this way, the argon gas is transported into the first material evaporating chamber U from the entire surface of the set of the fine holes Op of the gas introduction plate 125b at a low flow velocity without a deviation, as illustrated in FIG. 7B. Accordingly, a non-uniform shape or a backflow of the film forming material accommodated therein can be prevented. The gently introduced argon gas carries the film forming material vaporized from the first material evaporating chamber U into the transport mechanism 200 through the transfer path 115.

In this manner, by controlling the film forming rate with high accuracy and gasifying the film forming material completely, a high-quality film can be formed on the substrate G. Furthermore, by avoiding a degradation of a material efficiency due to a backflow of the material and a shortening of an apparatus maintenance cycle, manufacturing cost can be reduced, and throughput in the manufacturing process can be improved.

Moreover, as stated above, the argon gas is supplied from the gas supply port 130 at a flow rate of about 0.5 to sccm, and the argon gas is provided to the gas supply mechanism 105 from a through hole provided in the center of the flange 135. Further, the transport mechanism 200 and the deposition source unit 100 are connected with each other by a flange 140 installed at one end of the housing Hu.

The housing Hu accommodates therein the vapor deposition source assembly As in a detachable manner. When vapor deposition source assembly As is installed in the housing Hu, the vapor deposition source assembly As is first inserted in a space in the center of the housing Hu, and is fixed therein by inserting screws into a plurality of openings (not shown) in the flange 135 of the vapor deposition source assembly As and by engaging leading ends of the screws with screw receiver (not shown). With this configuration, since the material receptacle 110 can be easily attached and detached, replenishment of material can be readily carried out.

### EXPERIMENT

The inventors conducted a simulation as follows to investigate whether a temperature gradient is generated between the carrier gas and the vaporized film forming material when the carrier gas is introduced into the first material evaporating chamber U after passing through the gas passages 105p of the gas supply mechanism 105 in case of using the above-described deposition source unit 100.

As for conditions for the simulation, an argon gas was supplied as a carrier gas at a flow rate of about 10 sccm, and 42 gas passages 105p having a diameter φ of about 2 mm were provided in the gas supply mechanism 105. A temperature of the gas supply mechanism 105 was controlled to about 450° C.

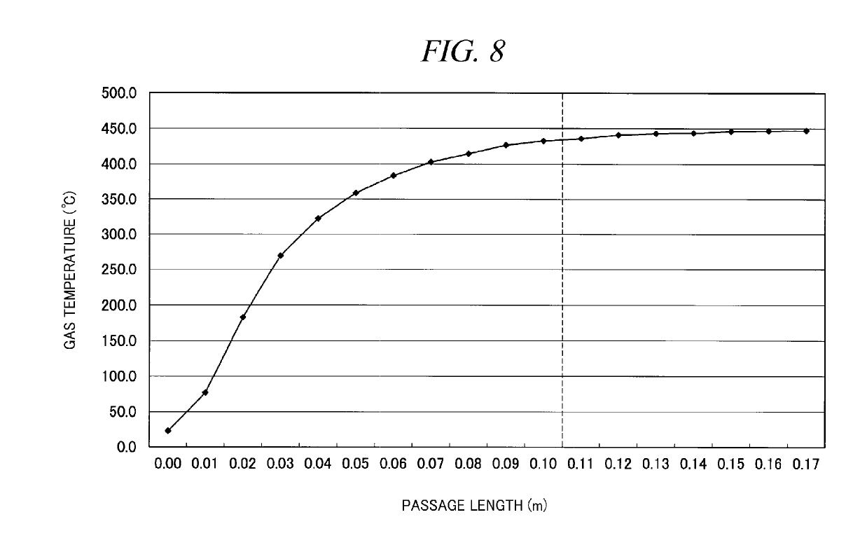

A simulation result under these conditions is shown in FIG. 8. As shown, when the length of each of the 42 gas passages 105p is about 0.105 m (=10.5 cm), the temperature of the argon gas is about 431.5° C. This level of temperature of the argon gas introduced into the first material evaporating chamber U is deemed to be the same as the temperature of the vaporized film forming material. As described above, the inventors proved that a film forming rate can be controlled with high accuracy by using the deposition apparatus 20 in accordance with the present embodiment if the length of the gas passage 105p is equal to or longer than about 10 cm based on the simulation result.

By using the deposition source unit 100 in accordance with the present embodiment, a high-quality film can be formed on the substrate G by controlling the film forming rate accurately.

### First Modification Example

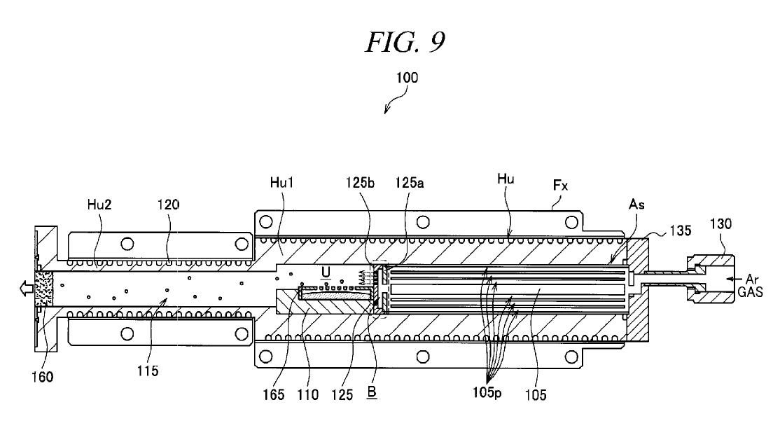

As illustrated in FIG. 9, a second material evaporating chamber (second material evaporating member) 160 may be installed at any position within the transfer path 115 to further vaporize the film forming material. At this time, the second material evaporating chamber 160 may be formed of a mesh-shaped metal member, a metal porous member, a lattice-patterned pore, an orifice, or the like.

The second material evaporating chamber 160 is installed at a position closer to the transport mechanism 200 than the first material evaporating chamber U. Since the transport mechanism 200 is typically controlled to about 450° C., a temperature of the second material evaporating chamber 160 is typically higher than a temperature of the first material evaporating chamber U. Accordingly, the film forming material passing through the transfer path 115 in the housing Hu is vaporized again when it passes through, for example, an opening of a mesh-shaped member or a gap between pores of a porous member. Accordingly, the film forming material transported by the carrier gas in an incompletely gasified state can be vaporized completely. As a result, a higher-quality film can be uniformly formed on the substrate G, and the material efficiency can be improved.

### Second Modification Example

Further, a cover 165 having lattice-patterned pores, mesh-shaped openings or hole-shaped openings may be detachably installed to the top of the first material evaporating chamber U of the deposition source unit 100 and serves as the top cover of the first material evaporating chamber U. With this configuration, the vaporized film forming material can flow toward the outside of the material receptacle 110 from the lattice-patterned pores, the mesh-shaped openings or hole-shaped openings, and a backflow of the film forming material in the material receptacle 110, which may be caused by a flow of the carrier gas transported into the first material evaporating chamber U, can be prevented.

As described above, a high-quality film can be formed on the substrate G by controlling a film forming rate with high accuracy in accordance with the first embodiment and modification examples.

(Temperature Controller)

Now, referring back to FIG. 5A, a temperature controller that controls a temperature of the deposition source unit 100 having the above-described configuration will be explained.

The temperature controller 180 includes a heating mechanism such as the heater 120 and a cooling mechanism such as the water cooling jacket 150. As discussed above, the heater 120 heats the argon gas whose flow velocity is reduced while it is passing through the narrow gas passages 105p. As a result, the argon gas can be heated up to the temperature substantially equivalent to the vaporization temperature of the film forming material. Further, the gas passages 105p are arranged so as to be uniformly heated by the heater 120.

The water cooling jacket 150 is installed apart from the outer peripheral surface of the housing Hu at a certain distance and cools the deposition source unit 100 by using a cooling water without being thermally affected by the adjacent deposition source unit. The water cooling jacket 150 is made of, e.g., stainless steel. It is desirable to install the water cooling jacket 150 apart from the outer peripheral surface of the housing Hu at a certain distance to uniformly cool the deposition source unit 100.

Conventionally, when performing maintenance for, e.g., material replenishment, the operation of the apparatus has to be stopped for almost a day until the deposition source unit is naturally cooled down. In accordance with the above-described configuration, however, maintenance time can be shortened because the deposition source unit 100 can be compulsively cooled by the water cooling jacket 150.

(Quantity of Heat Received by the Deposition Source Unit)

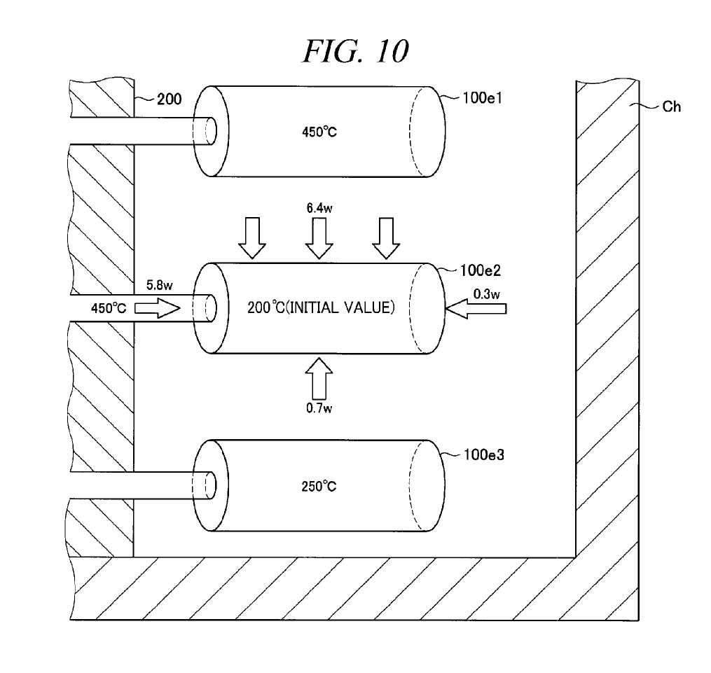

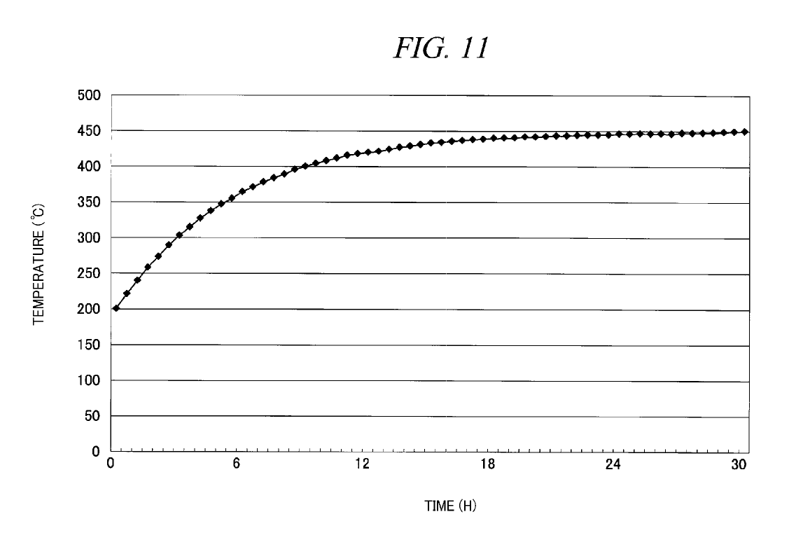

Here, a quantity of heat received by a deposition source unit 100e2 located at a center position will be explained with reference to FIGS. 10 and 11.

An average time (average residence time τ) during which molecules are in an adsorption state is expressed by τ=τ₀exp(Ea/kT), wherein Ea denotes an activation energy for desorption. Here, T is an absolute temperature; k is a Boltzman constant; and τ₀ is a specific constant. From this formula, it is known that the average residence time τ is a function of the absolute temperature and an adhesion coefficient decreases with an increase of the temperature (° C.). Based on this relationship, the temperature of the transport mechanism 200 that transports organic film forming molecules to the blowing port is typically set to be higher than the temperature of the deposition source unit 100 so as to allow the organic film forming molecules to reach the blowing port without adhering to the transport path.

In an initial state, assume that the transport mechanism 200 is controlled to about 450° C.; a deposition source unit 100e1 for accommodating a host material therein is controlled to about 450° C.; and deposition source units 100e2 and 100e3 for accommodating a dopant material therein are controlled to about 200° C. and about 250° C., respectively, for example.

At this time, the deposition source unit 100e2 receives heat of about 5.8 W from the transport mechanism 200 by heat conduction. Further, the deposition source unit 100e2 also receives heat of about 6.4 W, 0.7 W and 0.3 W from the adjacent deposition source units 100e1 and 100e3 and the adjacent sidewall of the processing chamber Ch by heat radiation, respectively.

In this way, each of the deposition source units 100e1 to 100e3 is heated to a high temperature by receiving heat conducted or radiated from the transport mechanism 200, the adjacent deposition source units and the sidewall of the processing chamber Ch. Especially, since the deposition source unit 100e2 located at the center-position receives radiated heat from the deposition source units 100e1 and 100e3 located at both sides thereof, its temperature is increased to a higher level.

For example, in case that the temperature of each of the adjacent deposition source units 100e1 and 100e3 is set to be about 450° C.; each of the deposition source units 100e1 to 100e3 has a bottle shape (cylindrical shape) having a diameter of about 40 mm and a length of about 110 mm; and each deposition source unit 100e is made of stainless steel, the temperature of the deposition source unit 100e2 located at the center-position increases from about 200° C. to 450° C. by the heat radiated from the adjacent components, i.e., the deposition source units 100e1 and 100e3 and the sidewall of the processing chamber Ch even when no heat is transferred from the transport mechanism 200, as illustrated in FIG. 11.

Meanwhile, FIG. 11 also shows that heat transfer efficiency is poor in the processing chamber Ch maintained at a specific vacuum degree and more than 20 hours is taken to raise the temperature of the deposition source unit 100e2 from about 200° C. to 450° C.

(Temperature Controller: Water Cooling Jacket)

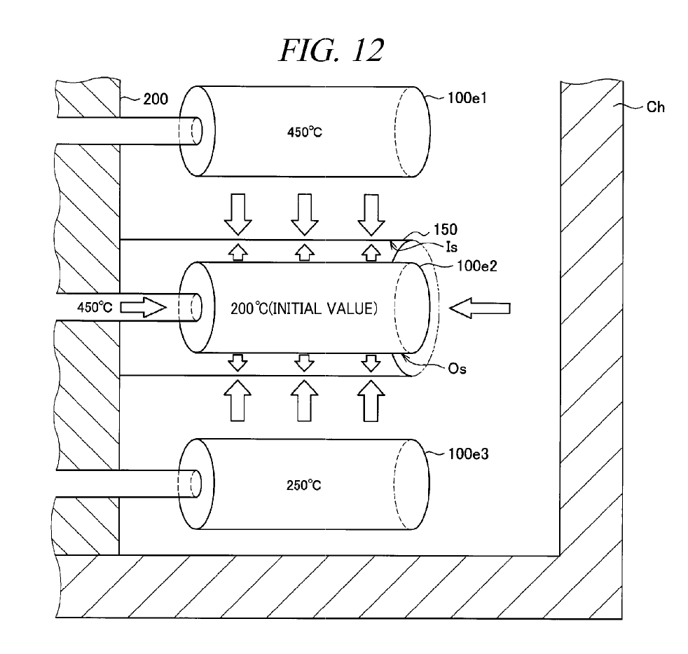

However, in the temperature controller 180 in accordance with the present embodiment, the water cooling jacket 150 is installed at a position distanced from the outer peripheral surface of the housing at a certain distance so as to surround the deposition source unit 100, as shown in FIG. 12. In this configuration, since the water cooling jacket 150 absorbs heat conducted and radiated from an adjacent deposition source unit 100 or adjacent members, an excessive temperature rise of the deposition source unit 100 can be avoided.

(Surface Roughness)

Further, the water cooling jacket 150 has a specific roughness on its surface facing the housing Hu. Likewise, the housing Hu also has a desired roughness on its surface facing the water cooling jacket 150.

Accordingly, an area of the water cooling jacket 150's surface facing the housing Hu or an area of the outer peripheral surface of the housing Hu increases. Thus, the housing can radiate the heat generated by the heater 120 to the outside effectively, and the water cooling jacket 150 can effectively absorb the heat generated by the heater 120 to the inside thereof.

(Absorption and Reflection of Light)

The water cooling jacket 150's surface facing the housing Hu may be processed so as to readily absorb heat. Further, the housing Hu's surface facing the water cooling jacket 150 may be processed so as to readily radiate the heat.

In this configuration, the housing radiates external heat whereas the water cooling jacket absorbs it. As a result, by allowing the housing Hu to have a high heat radiation rate and the water cooling jacket 150 to have a high heat absorption rate, the housing can be more efficiently cooled by the water cooling jacket 150 even under the vacuum where a heat transfer efficiency is poor, and an excessive temperature rise of the inside of the deposition source unit 100 can be prevented.

Further, the water cooling jacket 150's surface facing the housing Hu and the housing Hu's surface facing the water cooling jacket 150 may be processed by sandblast. However, the surface-processing by the sandblast is nothing more than an example for roughening a target surface, and fine irregularities can be formed on the surface by various kinds of mechanical processing besides the sandblast.

(Neck Portion of the Deposition Source Unit)

Further, the above-described deposition source unit of FIG. 5A has a bottle-shaped neck portion which is narrowed at a position where the transport path of the transport mechanism 200 and the transfer path 115 are connected with each other.

The bottle-shaped front portion (neck portion Hu2) of the deposition source unit has a small cross section, so that it has a higher heat resistance than that of the body portion (head portion Hu1) having a large cross section. With this configuration, the heat resistance of the neck portion Hu2 of the deposition source unit can be set to be higher than that of the head portion Hu1 of the deposition source unit. That is, heat transfer efficiency from the transport mechanism to the head portion Hu1 of the deposition source unit via the neck portion Hu2 thereof can be lowered. Accordingly, an excessive temperature rise of the first material evaporating chamber U in the head portion Hu1 of the deposition source unit can be suppressed.

(Metal Seal)

Further, a connection portion of the transfer path 115 and the transport mechanism 200 is sealed by metal seals 170. With this configuration, the transfer path 115 and the transport mechanism 200 can be hermetically sealed to prevent deterioration due to a heat from the transport mechanism 200.

Moreover, the connection portion of the transfer path 115 and the transport mechanism 200 may be configured to be in contact with only the metal seals 170 without in contact with any other material. In this configuration, since a non-contact portion is configured as a vacuum space, thermal conductivity from the transport path to the deposition source unit can be reduced by vacuum heat insulation. As a result, a temperature gradient is generated between the transport path and the deposition source unit, so that an excessive temperature rise of the inside of the deposition source unit 100 can be prevented.

Moreover, the above described water cooling jacket 150, the surface roughness on the inner surface of the water cooling jacket 150 or on the outer peripheral surface of the housing Hu, the neck portion Hu2 of the deposition source unit and the structure in the vicinity of the metal seals 170 of the deposition source unit 100 constitute an example of a cooling mechanism for cooling the deposition source unit 100.

(Temperature Controller: Heater)

Further, as for the temperature controller 180 of the present embodiment, the heater 120 is wound on the entire outer peripheral surface of the housing Hu as an example of heating mechanism to heat the argon gas passing through the plurality of gas passages 105p.

In this way, in the deposition apparatus 20 in accordance with the present invention, the deposition source unit 100 having the plurality of gas passages 105p therein can be controlled up to a desired temperature with high responsiveness by the heater 120 installed in the temperature controller 180 and the cooling mechanism such as the water cooling jacket 150 installed apart from the heater 120 at a certain distance. That is, after cooling the deposition source unit 100 to a temperature slightly lower than a target temperature, the temperature controller 180 heats the carrier gas supplied from the plurality of gas passages 105p by the heater 120 to a desired temperature.

As described above, the cooling mechanism is installed apart from the heating mechanism at a certain distance and the deposition source unit 100 serving as a temperature control target is previously cooled down to the temperature slightly lower than the target temperature, whereby the heating mechanism can quickly control the deposition source unit 100 up to the target temperature even in a vacuum where the heat transfer efficiency is poor. Further, by absorbing the heat generated from the heating mechanism by the cooling mechanism installed apart from the heating mechanism at a certain distance, a heat transfer to a component except the deposition source unit 100 as a target can be prevented. Accordingly, the temperature of the carrier gas can be quickly and accurately controlled to be the same as that of the film forming material vaporized from the material receptacle 110 even in the vacuum. As a result, a high-quality film can be formed on the substrate G.

(Experiment)

The inventors conducted a simulation as follows to investigate a temperature variation by the cooling and heating of the deposition source unit 100 by using the aforementioned temperature controller 180.

As shown in FIG. 12, the inventors assumed heat input from the transport mechanism 200 (position p0) is about 450° C. When the water cooling jacket 150 is operated without operating the heater 120 under this condition, the temperature of the first material evaporating chamber U of the deposition source unit 100 is maintained at about 200° C. in spite of the heat input of about 450° C. It implies that the heat transferred from the transport mechanism 200 can be effectively absorbed by the water cooling jacket 150.

From the above-described experiment, the inventors have proved that the deposition source unit 100 can be cooled to about 200° C. by the cooling mechanism including the water cooling jacket 150 and so forth when the heater 120 is not operated.

Subsequently, after cooling the deposition source unit 100 effectively under the condition of FIG. 5A, the inventors allowed the carrier gas to be heated by the heater 120 up to a desired temperature. A simulation result is provided in FIG. 5B.

At this time, the inventors assumed the heat input from the transport mechanism 200 (position p0) is about 450° C. Further, radiation coefficients ε at positions p1 to p6 are indicated by ε1 to ε6, respectively. The radiation coefficients ε are determined depending on the surface roughness of the inner surface Is of the water cooling jacket 150, the surface roughness of the outer peripheral surface Os of the housing Hu or shapes of the respective components of the deposition source unit 100.

As can be seen from the result of FIG. 5B, although the temperatures of the deposition source unit 100 at the respective positions p3 to p5 are high as about 450° C. for the heat input of about 450° C., its temperature at the position p6 in the vicinity of the outer periphery of the head portion Hu1 of the deposition source unit can be maintained well at about 250° C. by the effect of the cooling mechanism such as the water cooling jacket 150 shown at positions p1 and p2.

From the above-described experiment, the inventors have proved that the temperature of the carrier gas can be quickly and accurately controlled to be the same as that of the film forming material vaporized from the first material evaporating chamber U when both the heater 120 and the water cooling jacket 150 are operated, while a transfer of heat generated at a part of the deposition apparatus 20 to the first material evaporating chamber U by heat conductance and radiation is avoided. Thus, the inventors have succeeded in developing the deposition source unit 100 capable of forming the high-quality film on the substrate G by controlling a vaporization rate (i.e., a film forming rate on the target object) quickly and accurately even in the vacuum by a combination of the heating mechanism and the cooling mechanism.

Further, the inventors also conducted an experiment as to a temperature gradient from the transport mechanism 200 to the head portion Hu1 of the deposition source unit in case that a length of the neck portion Hu2 of the deposition source unit was set to about 100 mm.

As a result, when the temperature of the transport mechanism 200 was about 450° C., the temperature of the head portion Hu1 of the deposition source unit was about 390° C. This result proves that the neck portion Hu2 of the deposition source unit can be efficiently cooled by a synergy effect with the water cooling jacket 150 if the neck portion Hu2 is provided in the deposition source unit.

Moreover, as for a conventional deposition apparatus in which a carrier gas heating pipe is connected to the outside and as for the deposition source unit 100 in accordance with the present invention in which a gas heating mechanism (gas supply mechanism 105) is installed within the deposition source unit 100 instead of installing a long pipe to the outside of the vapor deposition source, the inventors investigated a variation of pressures within the vapor deposition sources.

As for conditions for the experiment, the carrier gas was flown at about 0.5 sccm, and a carrier gas introducing rate was set to about 8.44×10⁻⁴ (Pa·m³/s). In the conventional deposition apparatus in which the carrier gas heating pipe is connected to the outside, a simulation value and a measured value of an internal pressure of a bottle portion at the end of the were about 75 Pa. In comparison, an internal pressure of the deposition source unit 100 in accordance with the present embodiment was about 1 Pa, which is smaller than the conventional result by a one-digit place. Since pressure and temperature are proportional to each other, this result shows that the internal temperature of the deposition source unit 100 in accordance with the present invention is lower than the internal temperature of the bottle portion at the end of the pipe by the one-digit place.

In accordance with the deposition apparatus 20 of the present invention as described above, by heating the material receptacle 110 and the plurality of gas passages 105p by the heating mechanism while cooling the deposition source unit 100 in advance by the cooling mechanism even under the vacuum, the film forming rate can be quickly and accurately controlled, so that a high-quality film can be formed on the substrate G.

Further, the deposition apparatus 20 may have a configuration in which a plurality of deposition source units 100 is connected to the transport mechanism 200, and a water cooling jacket 150 is provided in at least one of the connected deposition source units 100.

With this configuration, the water cooling jacket 150 can prevent a temperature control within the deposition source unit 100 from being affected by heat radiated from the adjacent deposition source unit 100 as well as heat conductance or heat radiation from the transport mechanism 200. At this time, in case that the deposition source units 100 connected to the transport mechanism 200 are three or more, it may be desirable to install the water cooling jacket 150 at every deposition source unit 100. In case that the water cooling jacket cannot be installed at every unit, however, it may be desirable to first provide the cooling mechanism at a deposition source unit in a central position, which is most highly likely to be influenced by the heat radiation from each deposition source unit, or at a deposition source unit having a lowest control temperature.

In the above-described embodiment and modification examples, the argon gas has been used as the carrier gas. However, the carrier gas is not limited to the argon gas, but any non-reactive gas such as a helium gas, a krypton gas or a xenon gas may be employed.

In the present embodiment, the gas passages 105p were arranged in multi-levels to have a ring-shaped pattern with respect to the central axis O of the gas supply mechanism 105. However, the arrangement pattern of the gas passages 105p is not limited thereto. For example, the gas passages 105p may be installed in multi-levels from the lengthwise central axis O of the gas supply mechanism 105 toward an outer periphery (not in a ring-shaped pattern), or they may be installed in a ring-shaped pattern (not in multi-levels) from the lengthwise central axis O of the gas supply mechanism 105 toward the outer periphery. Moreover, the gas passages 105p may be arranged symmetrically or in a radial pattern with respect to the central axis O of the gas supply mechanism 105.

Further, there is no limit in a size of a glass substrate capable of being processed by the deposition apparatus 20 in accordance with the above-described embodiment and modification examples. For example, the deposition apparatus 20 can consecutively carry out the film formation on G4.5 substrates each having a size of about 730 mm×920 mm (internal diameter of chamber: about 1000 mm×1190 mm) or G5 substrates each having a size of about 1100 mm×1300 mm (internal diameter of chamber: about 1470 mm×1590 mm). Further, besides the glass substrate having the above-specified size, a silicon wafer of about 200 mm or 300 mm may be used as the target object processed by the deposition apparatus 20 in the above embodiment.

In the above-described embodiments, operations of respective components are interrelated and can be substituted with a series of operations in consideration of such an interrelation. By this substitution, the embodiment of the deposition apparatus can be applied to an embodiment of a method for using a deposition apparatus and an embodiment of a method for controlling a temperature of the deposition apparatus.

Though the above description has been provided with respect to the embodiment of the present invention in conjunction with the accompanying drawings, the present invention is not limited thereto. It would be understood by those skilled in the art that various changes and modifications may be made without departing from the scope of the invention as defined in the following claims. Those changes and modifications are all included in the technical scope of the present invention.

For example, in the deposition apparatus 20 in accordance with the above-described embodiment, an organic EL multi-layer film forming process is performed on the substrate G by using a powder-shaped (solid) organic EL material as a film forming material. However, the deposition apparatus in accordance with the present invention can also be employed in a MOCVD (Metal Organic Chemical Vapor Deposition) for forming a thin film on a target object by decomposing a film forming material vaporized from, e.g., a liquid organic metal above the target object heated up to about 500 to 700° C.

1. A deposition source unit configured to vaporize a film forming material and transport the vaporized film forming material by a carrier gas, the deposition source unit comprising:
a vapor deposition source assembly; and
a housing accommodating the vapor deposition source assembly,
wherein the vapor deposition source assembly includes:
a first material evaporating chamber configured to accommodate the film forming material therein and vaporize the accommodated film forming material; and
a gas supply mechanism having a plurality of gas passages, configured to flow the carrier gas in the gas passages to supply the carrier gas into the first material evaporating chamber, and
further wherein the housing includes a heating mechanism configured to heat the carrier gas flowing in the plurality of gas passages and the film forming material accommodated in the first material evaporating chamber.

2. The deposition source unit of claim 1, wherein the gas passages are provided along a lengthwise direction in parallel to each other.

3. (canceled)

4. (canceled)

5. (canceled)

6. The deposition source unit of claim 1, wherein the vapor deposition source assembly further includes a gas inlet between the first material evaporating chamber and the gas supply mechanism, the gas inlet configured as a single body with the first material evaporating chamber and the gas supply mechanism evaporating and having an opening for introducing the carrier gas flowing in the gas passages into the first material evaporating chamber.

7. (canceled)

8. (canceled)

9. The deposition source unit of claim 6, wherein the gas inlet includes a buffer space that temporarily stores the carrier gas between outlets of the gas passages and the opening of the gas inlet.

10. The deposition source unit of claim 1, wherein the heating mechanism is a heater installed at an outer periphery of the housing.

11. (canceled)

12. (canceled)

13. The deposition source unit of claim 1, wherein the housing includes a transfer path for transferring the film forming material vaporized from the first material evaporating chamber, and
the deposition source unit connects the transfer path to an external transport path so as to transport the film forming material from the transfer path to the transport path and blows off the transported film forming material from a blowing device.

14. The deposition source unit of claim 13, further comprising:
a second material evaporating chamber installed at a position within the transfer path, configured to further vaporize the film forming material.

15. (canceled)

16. A deposition apparatus comprising:
a deposition source unit configured to vaporize a film forming material and carry the vaporized film forming material by a carrier gas;
a transport path connected to the deposition source unit, for transporting the film forming material vaporized in the deposition source unit; and
a blowing device connected to the transport path, for blowing off the film forming material transported through the transport path,
wherein the deposition source unit includes a vapor deposition source assembly and a housing accommodating the vapor deposition source assembly,
further wherein the vapor deposition source assembly includes:
a first material evaporating chamber configured to accommodate the film forming material therein and vaporize the accommodated film forming material; and
a gas supply mechanism having a plurality of gas passages, configured to flow the carrier gas in the gas passages to supply the carrier gas into the first material evaporating chamber, and
further wherein the housing includes a heating mechanism configured to heat the carrier gas flowing in the plurality of gas passages and the film forming material accommodated in the first material evaporating chamber.

17. (canceled)

18. A temperature controller for controlling a temperature of a deposition source unit that is installed in a vacuum and vaporizes a film forming material and carries the vaporized film forming material by a carrier gas,
wherein the deposition source unit includes a plurality of gas passages for flowing therein the carrier gas which carries the vaporized film forming material,
further wherein the temperature controller includes:
a heating mechanism installed in the deposition source unit, configured to heat the carrier gas flowing in the plurality of gas passages; and
a cooling mechanism installed apart from the heating mechanism at a preset distance, configured to cool the deposition source unit.

19. (canceled)

20. (canceled)

21. The temperature controller of claim 18, wherein the deposition source unit includes:
a first material evaporating chamber for accommodating a film forming material therein and vaporizing the accommodated film forming material;
a vapor deposition source assembly having the plurality of gas passages; and
a housing accommodating the vapor deposition source assembly, and
further wherein the heating mechanism is installed in the vicinity of an outer periphery of the housing, and
the cooling mechanism is installed apart from an outer peripheral surface of the housing at a preset distance.

22. The temperature controller of claim 21, wherein a surface of the cooling mechanism facing the housing has a predetermined surface roughness.

23. The temperature controller of claim 21, wherein a surface of the housing facing the cooling mechanism has a predetermined surface roughness.

24. (canceled)

25. (canceled)

26. (canceled)

27. The temperature controller of claim 21, wherein the housing includes a transfer path for transferring the film forming material vaporized in the first material evaporating chamber, and
the transfer path is connected with an external blowing device installed outside via an external transport path so as to blow off the film forming material, which is transferred through the transfer path, from the blowing device.

28. The temperature controller of claim 27, wherein the deposition source unit has a bottle-shaped neck portion which is narrowed at a position where the transport path of the transport mechanism 200 and the transfer path 115 is connected with each other.

29. (canceled)

30. (canceled)

31. The temperature controller of claim 27, wherein a plurality of the blowing devices is arranged in parallel to each other, and
the cooling mechanism has a mechanism for flowing a coolant in partition walls configured to divide the plurality of blowing devices in the vicinity of the deposition source unit.

32. (canceled)

33. (canceled)

34. (canceled)

35. (canceled)
